(19) United States
(12) Patent Application Publication
(10) Pub. No.: US 2009/0091907 A1
(43) Pub. Date: Apr. 9, 2009

(54) Shielding structure for electronic components

(76) Inventors: Chung-Er Huang, Xindian (TW); Chien-Yu Huang, Xindian (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/905,993

(22) Filed: Oct. 9, 2007

(51) Int. Cl. H05K 9/00; C23C 30/00

(52) U.S. Cl. 361/818; 427/96.3

(57) ABSTRACT

A shielding structure for electronic components includes a circuit board, at least one electronic module disposed on the circuit board and electrically connected thereto, at least one first covering layer, at least one shielding layer, and one second covering layer. Each first covering layer covers one electronic module and each first covering layer is covered by the shielding layer. The second covering layer covers the shielding layers. In the above-mentioned structure, the shielding layer is formed by coating or printing on the first covering layer in order to shield the electromagnetic radiation emitted by the function module. The time and the costs required for the manufacture of the above invention are reduced compared to the prior art.

### BACKGROUND OF THE INVENTION

1. Field of the Invention

The present invention relates to a shielding structure for electronic components and in particular to a shielding structure used for preventing interference of electromagnetic signals with other electronic components or devices.

2. Description of Prior Art

Following the development of radio frequency technology, wireless communication systems are becoming more powerful and their performance increases. Demands on these systems are low weight, small dimensions, high quality, low energy-consumption high reliability, and low manufacturing costs. Another important function of wireless communication systems is the electric shielding of radiation emitted by their components in order to minimize interference of this radiation with other electronic devices or components.

However, up to the present the production of the shielding structures adds disproportional costs and time expenditure to the total manufacturing costs. In many cases the shielding structure is realised as a sheet steel casing around the wireless device or circuit module, necessitating the manufacture of costly dies for each shielding structure shape. Another currently employed method is to produce the casings by metal casting. In this case each shape to be cast requires the manufacture of a specific casting mold which involves manual work, leading to high costs. Furthermore, the assembly of the metal casings and the circuit modules is usually performed manually thus further increases costs.

Therefore, in light of the above mentioned shortcomings of the present state of the art, the inventor proposes the present invention to overcome the above problems based on his expert experience and research.

### SUMMARY OF THE INVENTION

The primary object of the present invention is to provide a shielding structure for electronic components made by coating or printing, thus increasing the efficiency of manufacturing and assembly and reducing manufacturing costs.

In order to achieve the above objects, the present invention provides a shielding structure for electronic components that comprises: a circuit board; at least one function module disposed on one side of the circuit board and electrically connected to the circuit board; at least one first covering layer covering the function module; at least one shielding layer covering the first covering layer; and a second or third covering layer covering the first or second shielding layer, respectively.

In order to realize the above design, the present invention provides a method for manufacturing the shielding structure. The method comprises (a) providing a circuit board; (b) connecting electrically at least one function module on one side of the circuit board; (c) disposing a first covering layer onto each of the function modules; (d) disposing a shielding layer onto each of the first covering layers; and (e) disposing a second covering layer onto the shielding layers.

The present invention further provides a shielding structure for multiple adjacent electronic components. The shielding structure comprises: a circuit board; a first and a second function module disposed on one side of the circuit board and electrically connected to the circuit board; a first covering layer covering the first function module; a first shielding layer covering the first covering layer; a second covering layer covering the first shielding layer and the second function module; a second shielding layer covering the second covering layer; and a third shielding layer covering the second covering layer.

In order to better understand the characteristics and technical contents of the present invention, a detailed description thereof will be made with reference to the accompanying drawings. However, it should be understood that the drawings and the description are illustrative and not intended to limit the scope of the present invention.

### BRIEF DESCRIPTION OF THE DRAWINGS

FIG. 1 is a schematic view showing the first embodiment of the shielding structure for electronic components according to the present invention;

FIG. 2 is a flow chart showing the method for manufacturing the shielding structure according to the present invention; and

FIG. 3 is a schematic view showing the second embodiment of the shielding structure for electronic components according to the present invention.

### DETAILED DESCRIPTION OF THE INVENTION

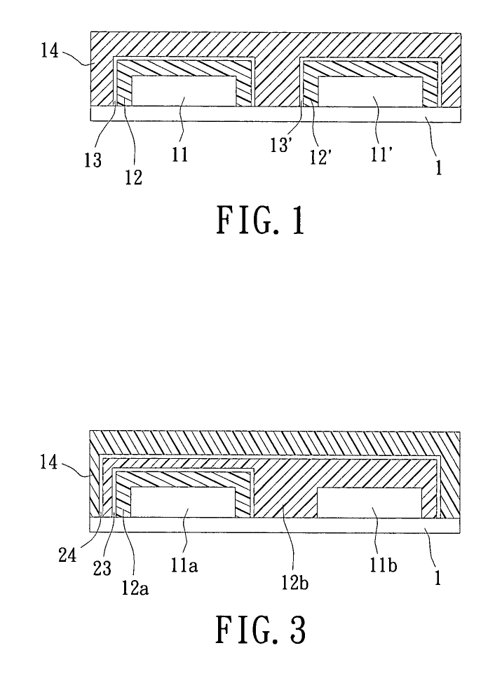

Please refer to FIG. 1. The invention discloses a shielding structure for a radio frequency (RF) module. The shielding structure is provided for preventing the interference of high frequency signals emitted by the module with other electronic devices or components.

The shielding structure for an RF module comprises a printed circuit board 1, made of Bismaleimide Triazine (BT) Resin. The circuit board 1 has a top side and a bottom side. A plurality of connecting lines such as ground line and transmitting lines are disposed on the top side of the circuit board 1, and the method for manufacturing the connecting lines is familiar to those skilled in the art.

Furthermore, at least one function module 11 is disposed on the top side of the circuit board 1 and electrically connected to the above-described connecting lines. In the first embodiment, two function modules 11 and 11′ are disposed on the top side of the circuit board 1 and the function modules 11 and 11′ are part of an RF device, such as a device for wireless Internet access, a Bluetooth device, or a global positioning system (GPS) device. The above-mentioned modules are examples for the embodiment but do not restrict the present invention.

A first covering layer 12 made of a thermal-melt polymer is molded onto the upper surface of each of the function modules 11. Thus, the two first covering layers 12 and 12′ completely cover the function modules 11 and 11′.

Please refer to FIG. 1. A shielding layer 13 is disposed onto the upper surface of each the first covering layers 12, and the shielding layer 13 is a metal layer applied by coating or printing so that the shielding layer 13 covers the first covering layer 12. The metal layer is grounded so that the high frequency signals emitted by the function module 11 are shielded. Accordingly, the interference of the signals with other electronic devices is reduced.

A second covering layer 14 covers all of the shielding layers 13 so as to form an integral protecting layer. In the first embodiment, the second covering layer 14 is disposed above the two shielding layers 13 and 13′. The second covering layer 14 can be of the same material as the first covering layers 12 or of a different material, depending on the application.

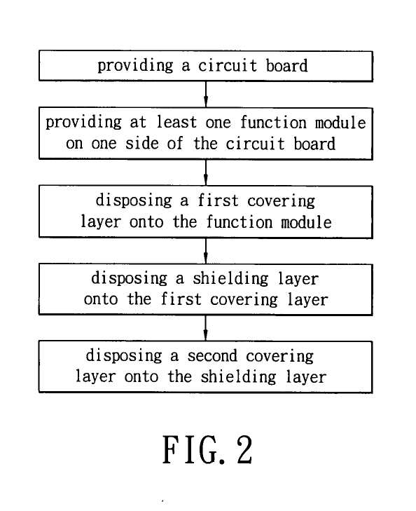

Please refer to FIG. 2, where the method for manufacturing the above-mentioned shielding structure is shown. The steps comprise: (a) providing a circuit board 1; (b) connecting electrically at least one function module 11 on the top side of the circuit board 1; (c) disposing a first covering layer 12 onto the upper surface of each the function modules 11; (d) disposing a shielding layer 13 onto the upper surface of each of the first covering layers 12; and (e) disposing a second covering layer 14 onto the shielding layer 13. In step (a), a Bismaleimide Triazine (BT) board is provided. In step (c) the shape of the first covering layer 12 corresponds to the shape of the function modules 11, because the first covering layer 12 is molded around the upper surface of each the function modules 11, thus covering completely the function modules 11 and 11′. In step (d), the shielding layer 13 is a metal layer applied by coating or printing. Thus, the manufacturing time and costs are reduced compared to the prior art. Furthermore, the shape and the dimensions of the metal layer formed by coating or printing will automatically follow the shape of the first covering layer 12, which in turn adapts to the shape of the function module. Thus, the manufacturing process for the present invention can be applied to many kinds of function modules. Moreover, the thickness of the shielding layer 13 can be precisely controlled in the coating or printing process, and thus the precision of the metal layer is improved.

Please refer to FIG. 3, where the second embodiment of the present invention is shown. The shielding structure for an RF device comprises a printed circuit board 1, made of Bismaleimide Triazine (BT) Resin. A first RF function module 11a and a second RF function module 11b are disposed on the top side of the circuit board 1 and electrically connected to the circuit board 1. A first covering layer 12a is covering the first function module 11a and a first shielding layer 23 is covering the first covering layer 12a, leading to ground the signals emitted by the function module 11a. A second covering layer 12b is covering the first shielding layer 23 and the second function module 11b. A second shielding layer 24 is covering the second covering layer 12b. Depending on the requirements, the second shielding layer 24 can be omitted. The first shielding layer 23 is shielding the second function module 11b from the signal of the first function module 11 a and vice versa. The second shielding layer 24 prevents the signals emitted by the second function module 11b from interfering with other high frequency devices (not shown). A third covering layer 14 covers the second shielding layer 24 so that the assembly is protected. Note that the number of function modules 11 is not limited to the number of function modules in the above embodiment. The shielding structure of the present invention can be employed in RF devices with multiple function modules for efficiently preventing the signals emitted by the modules from interfering with the other modules of the assembly or with adjacent electronic devices.

The manufacturing method for the second embodiment is the same as the method disclosed in the first embodiment, including the coating method for applying a metal layer.

In summary, the present invention achieves the following advantages:

1. The shielding layer provided for shielding the emitted radio frequency signal is formed by coating or printing so that manufacturing time and costs can be reduced compared to the traditional methods such as metal-punching, which rely on manual labour and thus incur extremely high costs. Furthermore, the thickness and the dimensions of the shielding layer can be precisely controlled in the manufacturing process so that the shielding layer can be adapted to many kinds of applications.

2. The shielding structure is provided for shielding the environment from the signals emitted by different modules. However, the structure of the present invention can also prevent the different modules from interfering with each other.

Although the present invention has been described with reference to the foregoing preferred embodiment, it shall be understood that the invention is not limited to the details thereof. Various equivalent variations and modifications may occur to those skilled in this art in view of the teachings of the present invention. Thus, all such variations and equivalent modifications are embraced within the scope of the invention as defined in the appended claims.

What is claimed is:

1. A shielding structure for electronic components comprising:
a circuit board;
a plurality of function modules disposed on one side of the circuit board and electrically connected to the circuit board;
a plurality of first covering layers covering each of the function modules;
a plurality of shielding layers covering the first covering layers; and
a second covering layer covering the shielding layers.

2. The shielding structure according to claim 1, wherein the function modules are radio frequency (RF) modules.

3. The shielding structure according to claim 1, wherein the first covering layers and the second covering layers are made from a thermal-melt polymer.

4. The shielding structure according to claim 1, wherein the shielding layers are metal layers.

5. The shielding structure according to claim 4, wherein the metal layers are formed by coating or printing.

6. The shielding structure according to claim 1, wherein the shielding layers are grounded.

7. A method for manufacturing the shielding structure according to claim 1 comprising:
(a) providing a circuit board;
(b) connecting electrically a plurality of function modules on one side of the circuit board;
(c) disposing a first covering layer onto each of the function modules;
(d) disposing a shielding layer onto each of the first covering layers; and
(e) disposing a second covering layer onto the shielding layers.

8. The method according to claim 7, wherein the shielding layer of step (d) is a metal layer formed by coating or printing.

9. The method according to claim 7, wherein the first covering layer and the second covering layer are made from a thermal-melt polymer.

10. The method according to claim 7, wherein the function modules are radio frequency (RF) modules.

11. A shielding structure for electronic components comprising:
a circuit board;
a first function module disposed on one side of the circuit board and electrically connected to the circuit board;
a first covering layer covering the first function module;
a first shielding layer covering the first covering layer;
a second function module disposed on the side of the circuit board and electrically connected to the circuit board;
a second covering layer covering the second function module and the first shielding layer; a second shielding layer covering the second covering layer; and
a third covering layer covering the second shielding layer.

12. The shielding structure according to claim 11, wherein the first function module and the second function module are radio frequency (RF) modules.

13. The shielding structure according to claim 11, wherein the first covering layer and the second covering layer are made from a thermal-melt polymer.

14. The shielding structure according to claim 11, wherein the first shielding layer and the second shielding layer are metal layers.

15. The shielding structure according to claim 14, wherein the metal layers are formed by coating or printing.

16. The shielding structure according to claim 11, comprising a second covering layer disposed between the first shielding layer and the second shielding layer.
